(19) United States
(12) Patent Application Publication
(10) Pub. No.: US 2018/0288883 A1
(43) Pub. Date: Oct. 4, 2018

(54) PRODUCING METHOD OF SUSPENSION BOARD WITH CIRCUIT ASSEMBLY

(71) Applicant: NITTO DENKO CORPORATION, Osaka (JP)

(72) Inventors: Takatoshi SAKAKURA, Osaka (JP); Hitoki KANAGAWA, Osaka (JP)

(73) Assignee: NITTO DENKO CORPORATION, Osaka (JP)

(21) Appl. No.: 15/928,599

(22) Filed: Mar. 22, 2018

(30) Foreign Application Priority Data
Mar. 28, 2017 (JP) 2017-062238

(51) Int. Cl. H05K 3/34

(52) U.S. Cl. CPC H05K 3/3494; H05K 3/341

(57) ABSTRACT

A method for producing a suspension board with circuit assembly includes a preparing step of preparing a plurality of board assemblies each of which includes a plurality of suspension boards with circuit including a first terminal, a supporting portion collectively supporting the plurality of suspension boards with circuit, and a plurality of connecting portions connecting each of the suspension boards with circuit to the supporting portion; an assembly disposing step of disposing the plurality of board assemblies on a carrier board; a solder disposing step of disposing a first solder on the first terminal; an element disposing step of disposing an electronic element so as to be in contact with the first solder; and a reflow step of heating the first solder to be dissolved and connecting the electronic element to the first terminal. The solder disposing step, the element disposing step, and the reflow step are continuously performed.

### CROSS-REFERENCE TO RELATED APPLICATION

The present application claims priority iron Japanese Patent Application No. 2017-062238 filed on Mar. 28, 2017, the contents of which are hereby incorporated by reference into this

### BACKGROUND OF THE INVENTION

### Field of the Invention

The present invention relates to a method for producing a suspension board with circuit assembly.

### Description of Related Art

Conventionally, it has been known that aa electronic element is mounted on a suspension board with circuit.

For example, a method for producing a suspension board with circuit has been proposed in which a suspension board assembly including a plurality of suspension boards is prepared; a solder is printed on a terminal included in each of the suspension boards; thereafter, an electronic element is disposed on each of the suspension boards; and next, the electronic element is soldered to the terminal by reflow (ref: for example, Japanese Unexamined Patent Publication No. 2016-31770).

### SUMMARY OF THE INVENTION

In the suspension board assembly described in Japanese Unexamined Patent Publication No. 2016-31770, the plurality of suspension boards are disposed at spaced intervals to each other, and supported by being connected to a frame body. Thus, the rigidity of the suspension board assembly cannot be sufficiently ensured, and the suspension board assembly cannot be stably conveyed.

As a result, in the method for producing the suspension board with circuit described in Japanese Unexamined Patent Publication No. 2016-31770, each of the steps (step of printing the solder, step of disposing the electronic element, reflow step, or the like) is performed for the one suspension board assembly by a single wafer method, and the conveyance is manually performed between each of the steps, so that the suspension board with circuit mounted with the electronic element is produced.

However, the electronic element such as a piezoelectric element is required to have strict position accuracy on the suspension board with circuit so as to ensure a stable movement and to avoid a contact with members around it.

In the method for producing the suspension board with circuit described in Japanese Unexamined Patent Publication No. 2016-31770, the single wafer method is performed, so that when a plurality of times are performed, there may be a ease where the amount of solder printed and the reflow temperature in each single wafer treatment vary. Then, the position of the electronic element with respect to each of the suspension boards varies among the plurality of single wafer treatments caused by an uneven amount of printed solder and an uneven reflow temperature.

Thus, in the method for producing the suspension board with circuit described in Japanese Unexamined Patent Publication No. 2016-31770, there is a limit in improvement of the position accuracy of the electronic element, and it is difficult to improve the production efficiency of the suspension board with circuit mounted with the electronic element.

The present invention provides a method for producing a suspension board with circuit assembly capable of improving the position accuracy of an electronic element and improving the production efficiency.

The present invention [1] includes a method for producing a suspension board with circuit assembly including a preparing step of preparing a plurality of board assemblies each of which includes a plurality of suspension boards with circuit including a first terminal and disposed at spaced intervals to each other, a supporting portion collectively supporting the plurality of suspension boards with circuit, and a plurality of connecting portions connecting each of the plurality of suspension boards with circuit to the supporting portion; an assembly disposing step of disposing the plurality of board assemblies on a carrier board to be in alignment; a solder disposing step of disposing a first solder on the first terminal of each of the plurality of suspension boards with circuit; an element disposing step of disposing an electronic element so as to be in contact with the first solder disposed on each of the plurality of first terminals; and a reflow step of heating the first solder to be dissolved and connecting the electronic element to the first terminal, wherein the solder disposing step, the element disposing step, and the reflow step are continuously performed.

According to the method, the plurality of board assemblies are disposed on the carrier board to be in alignment, so that the plurality of board assemblies can be collectively conveyed, and the solder disposing step, the element disposing step, and the reflow step can be continuously performed with respect to the plurality of board assemblies.

Thus, unevenness in the amount of the first solder disposed on the first terminal in the solder disposing step and unevenness in the heating temperature with respect to the first solder in the reflow step among the plurality of board assemblies can be suppressed. As a result, unevenness in the position of the electronic element with respect to the suspension board with circuit among the plurality of board assemblies can be suppressed.

In this manner, improvement of the position accuracy of the electronic element can be achieved, and improvement of the production efficiency of the suspension board with circuit assembly can be achieved.

The present invention [2] includes the method for producing a suspension board with circuit assembly described in the above-described [1], wherein the first terminal is exposed when viewed from one side in a thickness direction of the suspension board with circuit, each of the plurality of suspension boards with circuit further includes a second terminal exposed when viewed from the other side in the thickness direction of the suspension board with circuit and a second solder disposed on the second terminal, the carrier board has a recessed portion and/or an opening, and in the assembly disposing step, the plurality of board assemblies are disposed on the carrier board so that the second solder is disposed in the recessed portion and/or the opening.

When the second solder disposed on the second terminal is brought into contact with the carrier board, the suspension board with circuit may be slightly deformed. When the suspension board with circuit is deformed, the first terminal deviates from a predetermined position, so that in the solder disposing step, the first solder cannot be accurately disposed on the first terminal.

Meanwhile, in the above-described method, the plurality of board assemblies are disposed on the carrier board so that the second solder is disposed in the recessed portion and/or the opening. Thus, the contact of the second solder with the carrier board can be suppressed. As a result, the position deviation of the first terminal can be suppressed, and in the solder disposing step, the first solder can be accurately disposed on the first terminal.

The present invention [3] includes the method for producing a suspension board with circuit assembly described in the above-described [1] or [2], wherein the carrier board includes a fluorine-based pressure-sensitive adhesive layer for fixing the position of the plurality of board assemblies.

The board assembly may thermally contract. Thus, in the reflow step, when the adhesive properties of the carrier board with the board assembly are excessively high, the board assembly thermally contracts in a state of being bound to the carrier board, and a wrinkle occurs in the board assembly.

Meanwhile, according to the above-described method, the carrier board includes the fluorine-based pressure-sensitive adhesive layer, and the position of the plurality of board assemblies is fixed by the fluorine-based pressure-sensitive adhesive layer. Thus, the adhesive properties of the fluorine-based pressure-sensitive adhesive layer with the board assembly in the reflow step are preferably adjusted, and the occurrence of the wrinkle in the board assembly can be suppressed.

The present invention [4] includes the method for producing a suspension board with circuit assembly described in any one of the above-described [1] to [3], wherein the electronic element is a piezoelectric element, and in the reflow step, the piezoelectric element is connected to the first terminal, while being self aligned.

According to the method, in the reflow step, the piezoelectric element is connected to the first terminal, while being self-aligned, so that improvement of the position accuracy of the piezoelectric element can be achieved.

### BRIEF DESCRIPTION OF THE DRAWINGS

FIG. 1 shows one embodiment of a preparing step according to a method for producing a suspension board with circuit assembly of the present invention.

FIG. 2 shows a plan view of one embodiment of a carrier board according to a method for producing a suspension board with circuit assembly of the present invention.

FIG. 3 shows an assembly disposing step of disposing a plurality of board assemblies shown in FIG. 1 on the carrier board.

FIG. 4 shows a plan view of a suspension board with circuit shown in FIG. 3.

FIG. 5 shows a bottom view of the suspension board with circuit shown in FIG. 4.

FIG. 6A shows an A-A cross-sectional view of an element mounting terminal shows in FIG. 4.

FIG. 6B shows a B-B cross-sectional view of a magnetic head terminal shown in FIG. 5.

FIG. 7A shows a solder disposing step of disposing a first solder on a first terminal.

FIG. 7B shows an element disposing step of disposing an electronic element.

FIG. 7C shows a reflow step of connecting the electronic element to the first terminal.

FIG. 8 shows an explanatory view for explaining the self-alignment of a piezoelectric element in the reflow step shown in FIG. 7C.

FIG. 9 shows one embodiment of a continuous mounting line in which the solder disposing step shown in FIG. 7A, the element disposing step shown in FIG. 7B, and the reflow step shown in FIG. 7C are continuously performed.

FIG. 10 shows another embodiment (embodiment in which a plurality of board assemblies are united) of the preparing step.

### DETAILED DESCRIPTION OF THE INVENTION

A method for producing a suspension board with circuit assembly of the present invention includes a preparing step of preparing a plurality of board assemblies including a plurality of suspension boards with circuit, an assembly disposing step of disposing the plurality of board assemblies on a carrier board, a solder disposing step of disposing a first solder on a first terminal of each of the suspension hoards with circuit, an element disposing step of disposing an electronic element so as to be in contact with the first solder, and a reflow step of connecting the electronic element to the first terminal. The solder disposing step, the element disposing step, and the reflow step are continuously performed.

### FIRST EMBODIMENT

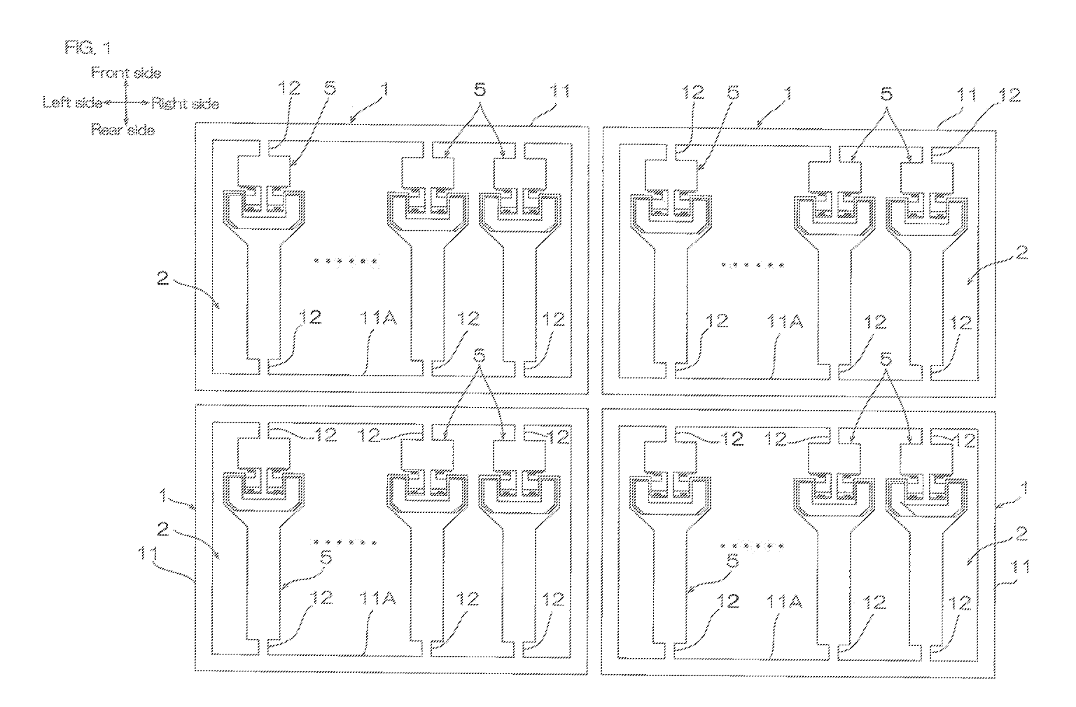

In the following, a first embodiment of the present invention is described with reference to FIGS. 1 to 9.

In FIG. 1, the up-down direction of the paper surface is a front-rear direction (first direction), the upper side of the paper surface is a front side (one side in the first direction), and the lower side of the paper surface is a rear side (the other side in the first direction).

In FIG. 1, the right-left direction of the paper surface is a right-left direction (second direction perpendicular to the first direction), the left side of the paper surface is a left side (one side in the second direction), and the right side of the paper surface is a right side (the other side in the second direction).

In FIG. 1, the paper thickness direction of the paper surface is an up-down direction (third direction perpendicular to the first direction and the second direction), the near side of the paper surface is an upper side (one side in the third direction), and the far side of the paper surface is a lower side (the other side in the third direction). To be specific, directions are in conformity with direction arrows of each view.

1. Preparing Step

As shown in FIG. 1, in the preparing step, a plurality of board assemblies 1 are prepared. In the embodiment, in FIG. 1, the four board assemblies 1 are prepared for convenience, and the number of board assembly 1 to be prepared is not particularly limited. The number of board assembly 1 to be prepared is 2 or more, preferably 6 or more, and for example, 30 or less, preferably 20 or less.

The board assembly 1 includes a suspension group 2, a frame body 11 as one example of a supporting portion that supports the suspension group 2, and a plurality of connecting portions 12 that connect the suspension group 2 to the frame body 11.

The suspension group 2 is made up of a plurality of suspension boards with circuit 5. That is, the board assembly 1 includes the plurality of suspension boards with circuit 5. In the suspension group 2, the plurality of suspension boards with circuit 5 are disposed in parallel at spaced intervals to each other in the right-left direction (one example of a direction perpendicular to the thickness direction of the suspension board with circuit).

(1-1) Suspension Board with Circuit

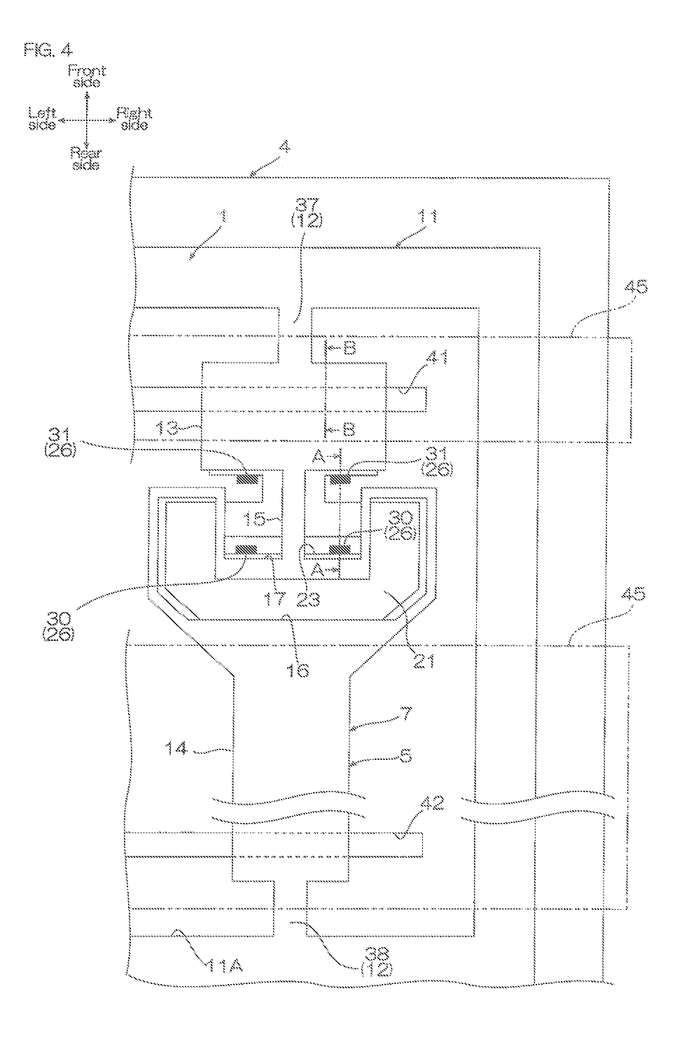

The suspension board with circuit 5 is described with reference to FIGS. 4 to 6A.

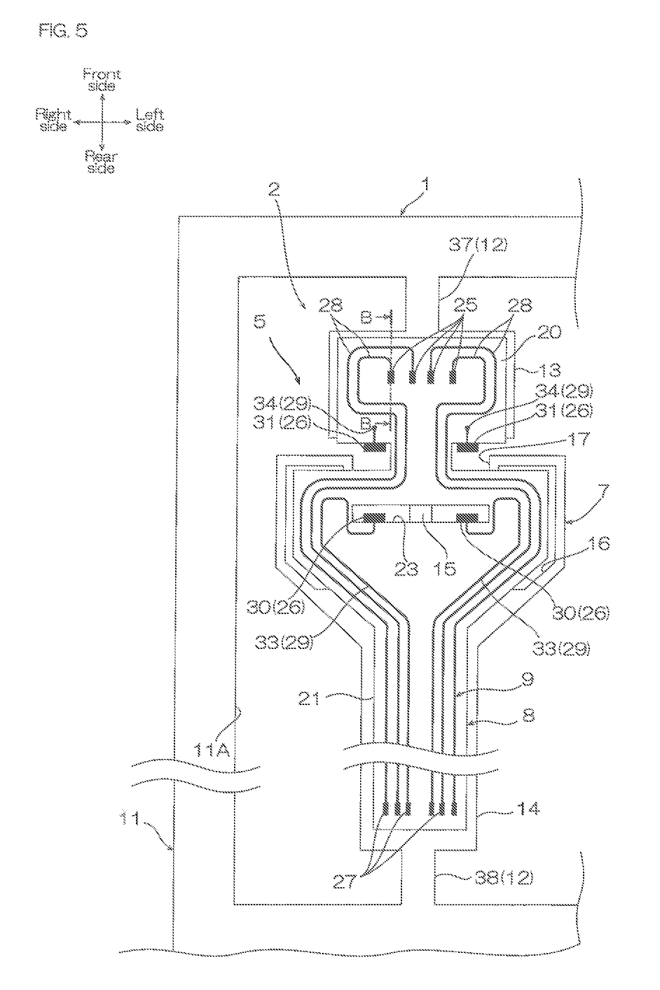

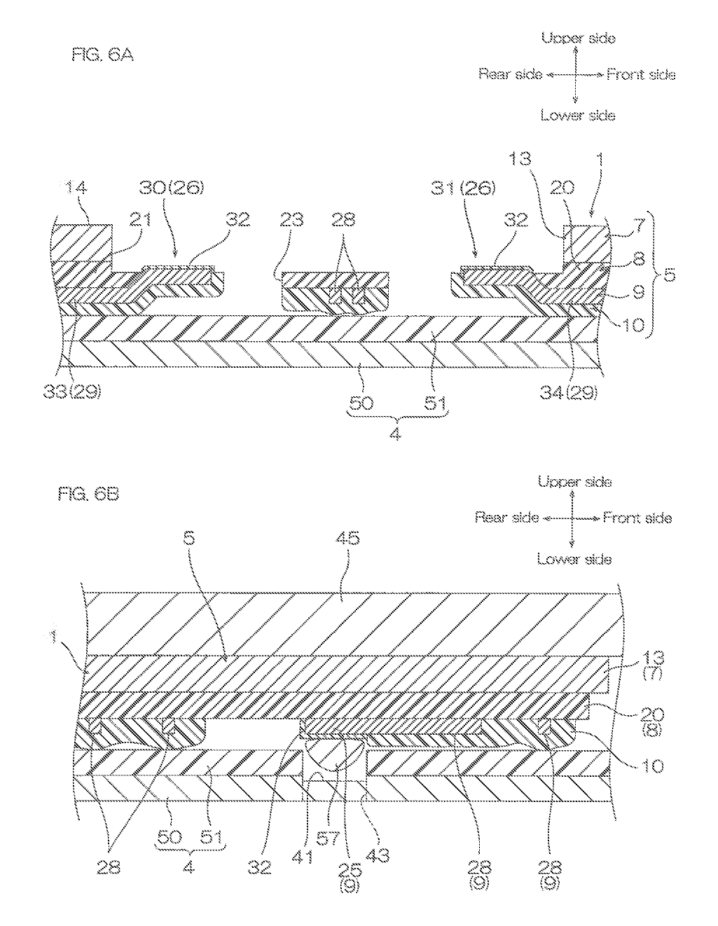

As shown in FIG. 4, the suspension board with circuit 5 has a flat belt shape extending in the front-rear direction. As shown in FIG. 6A, the suspension board with circuit 5 sequentially includes a metal supporting body 7, a base insulating layer 8, a conductive pattern 9, and a cover insulating layer 10 from the upper side (one example of one side in the thickness direction) toward the lower side (one example of the other side in the thickness direction). In FIG. 5, the cover insulating layer 10 is omitted for convenience.

As shown in FIG. 4, the metal supporting body 7 extends in the front-rear direction. The metal supporting body 7 includes a stage 13, a suspension main body 14, and a bridge portion 15.

The stage 13 is the front end portion of the metal supporting body 7, and has a generally rectangular shape when viewed from the top.

The suspension main body 14 is disposed at the rear side of the stage 13. The suspension main body 14 has a fiat belt shape extending in the front-rear direction. The front side portion of the suspension main body 14 has an opening portion 16. The opening portion 16 has a recessed shape that opens toward the front side. The front end portion of the suspension main body 14 forms a recessed portion 17 that is recessed toward the rear side along the opening portion 16.

The bridge portion 15 connects the rear end edge of the stage 13 to the front end edge of the suspension main body 14.

As example of a material of the metal supporting body 7 includes a metal material such as stainless steel. The metal supporting body 7 has a thickness of, for example, 10 μm or more, preferably 15 μm or more, and for example, 35 μm or less, preferably 25 μm or less.

As shown in FIG. 6A, the base insulating layer 8 is disposed on the lower surface of the metal supporting body 7. As shown in FIG. 5, the base insulating layer 8 is provided as a predetermined pattern corresponding to the conductive pattern 9. The base insulating layer 8 includes a stage base 20 and a main body base 21.

The stage base 20 is disposed on the lower surface of the stage 13. The stage base 20 has a generally rectangular shape when viewed from the bottom. The rear end edge of the stage base 20 is positioned at the rear side with respect to the rear end edge of the stage 13.

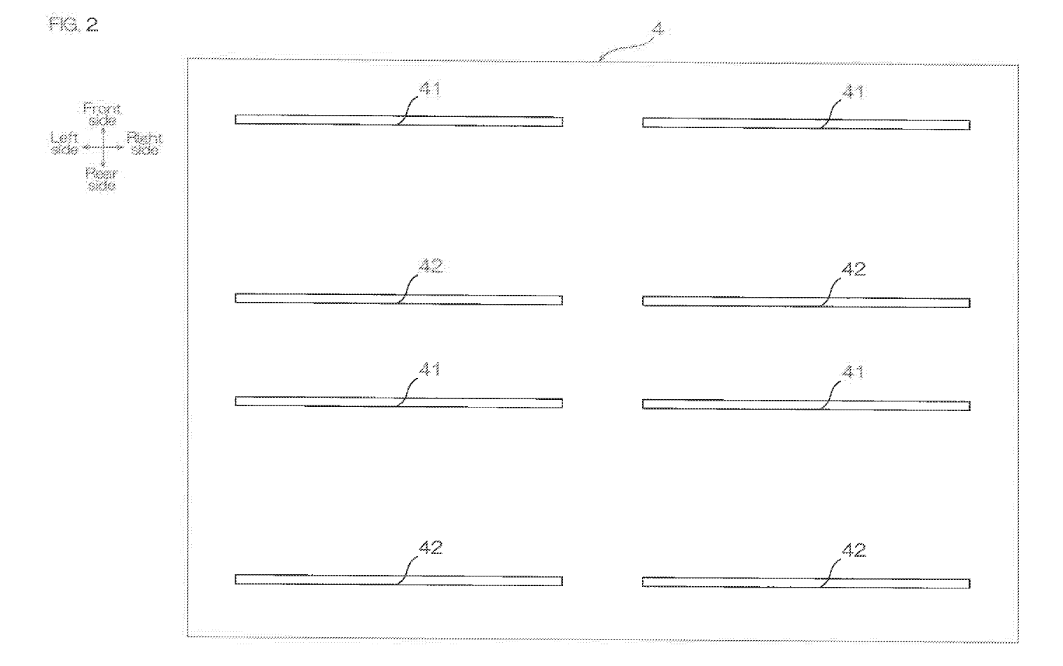

The main body base 21 is disposed on the lower surface of the suspension main body 14. The main body base 21 has an opening portion 23 in a position overlapped with the recessed portion 17 (ref: FIG. 2) when viewed in the up-down direction. The opening portion 23 has a generally rectangular shape when viewed from the bottom extending in the right-left direction. The rear end edge of the opening portion 23 is positioned at the front side with respect to the rear end edge of the recessed portion 17 (ref: FIG. 4).

An example of a material of the base insulating layer 8 includes a synthetic resin such as polyimide resin. The base insulating layer 8 has a thickness of, for example, 1 μm or more, preferably 3 μm or more, and for example, 25 μm or less, preferably 15 μm or less.

As shown in FIG. 6A, the conductive pattern 9 is disposed on the lower surface of the base insulating layer 8. As shown in FIG. 5, the conductive pattern 9 includes a plurality (four pieces) of magnetic head terminals 25 as one example of a second terminal, a plurality (four pieces) of element mounting terminals 26 as one example of a first terminal, a plurality (six pieces) of external connecting terminals 27, a plurality (four pieces) of magnetic head wires 28, and a plurality (four pieces) of element wires 29.

When a slider that is not shown is mounted on the suspension board with circuit 5, the plurality (four pieces) of magnetic head terminals 25 are electrically connected to a magnetic head included in the slider via slider connecting solders 57 (ref: FIG. 6B). The plurality of magnetic head terminals 25 are disposed at spaced intervals to each other in the right-left direction on the stage base 20.

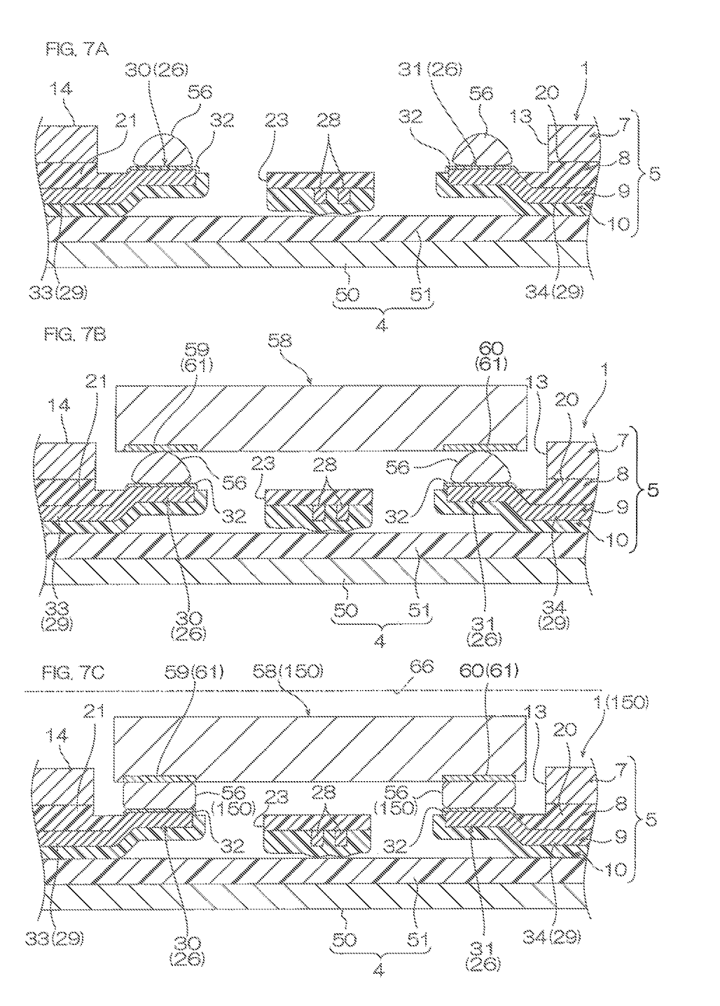

When piezoelectric elements 58 to be described later are mounted on the suspension board with circuit 5, the plurality (four pieces) of element mounting terminals 26 are electrically connected to the piezoelectric elements 58 via element connecting solders 56 (ref: FIG. 7C). The plurality of element mounting terminals 26 include a plurality (two pieces) of first mounting terminals 30 and a plurality (two pieces) of second mounting terminals 31.

As shown in FIGS. 5 and 6A, the plurality of first mounting terminals 30 are disposed in the opening portion 23, and disposed at spaced intervals to each other in the right-left direction. The plurality of first mounting terminals 30 are next to the front side with respect to the rear end edge of the opening portion 23. The first mounting terminals 30 extend so as to be apart from the base insulating layer 8 that is next thereto, and are exposed from the metal supporting body 7 and the base insulating layer 8 when viewed from the upper side.

The plurality of second mounting terminals 31 are next to the rear side with respect to the rear end edge of the stage base 20. The plurality of second mounting terminals 31 are disposed at spaced intervals to each other in the right-left direction. The second mounting terminals 31 are positioned at spaced intervals to the front side with respect to the first mounting terminals 30.

The second mounting terminals 31 extend so as to be apart from the base insulating layer 8 (the stage base 20) that is next thereto, and are exposed from the metal supporting body 7 and the base insulating layer 8 when viewed from the upper side. That is, the plurality of element mounting terminals 26 are exposed when viewed from the upper side (one side in the thickness direction of the suspension board with circuit 5).

As shown in FIG. 5, the plurality (six pieces) of external connecting terminals 27 are disposed at spaced intervals to each other in the right-left direction on the rear end portion of the main body base 21.

As shown in FIGS. 6A and 6B, a plating layer 32 is provided on each of the lower surfaces of the plurality of magnetic head terminals 25, each of the upper surfaces of the plurality of element mounting terminals 26 (the first mounting terminals 30 and the second mounting terminals 31), and each of the lower surfaces of the plurality of external connecting terminals 27. An example of a material of the plating layer 32 includes a metal material such as nickel and gold. Preferably, gold is used. The plating layer 32 has a thickness of, for example, 0.1 μm or more, preferably 0.25 μm or more, and for example, 5 μm or less, preferably 2.5 μm or less.

As shown in FIG. 5, the plurality (four pieces) of magnetic head wires 28 electrically connect the plurality of magnetic head terminals 25 to the external connecting terminals 27 having the same number as that of the plurality of magnetic head terminals 25.

The plurality (four pieces) of element wires 29 are connected to the plurality of element mounting terminals 26. To be more specific, the plurality of element wires 29 include a plurality of power source wires 33 that are connected to the plurality of first mounting terminals 30 and a plurality of ground wires 34 that are connected to the plurality of second mounting terminals 31.

As shown in FIG. 6A, the power source wire 33 is connected to the rear end portion of the first mounting terminal 30, and disposed on the main body base 21 so as to form a difference in level with the first mounting terminal 30. As shown in FIG. 5, the plurality of power source wires 33 electrically connect the plurality of first mounting terminals 30 to the external connecting terminals 27 that are not connected to the magnetic head wires 28 of the plurality of external connecting terminals 27.

As shown in FIG. 6A, the ground wire 34 is connected to the front end portion of the second mounting terminal 31, and disposed on the stage base 20 so as to form a difference in level with the second mounting terminal 31. As shown in FIG. 5, the plurality of ground wires 34 pass through the stage base 20 to be brought into contact with (grounded to) the stage 13.

An example of a material of the conductive pattern 9 includes a conductive material such as copper. The conductive pattern 9 has a thickness of, for example, 1 μm or more, preferably 3 μm or more, and for example, 20 μm or less, preferably 12 μm or less.

As shown in FIGS. 6A and 6B, the cover insulating layer 10 is disposed on the lower surface of the conductive pattern 9 and a portion that is exposed from the conductive pattern 9 on the lower surface of the base insulating layer 8 so as to covet the conductive pattern 9. To be more specific, the cover insulating layer 10 has a pattern shape of exposing the magnetic head terminal 25 and the external connecting terminal 27 and covering the element mounting terminal 26, the magnetic head wire 28, and the element wire 29 when viewed from the lower side (the other side in the thickness direction). That is, the plurality of magnetic head terminals 25 are exposed when viewed from the lower side (the other side in the thickness direction of the suspension board with circuit 5).

As a material of the cover insulating layer 10, for example, the synthetic resin that is the same as that of the base insulating layer 8 is used. The thickness of the cover insulating layer 10 is appropriately set.

The slider connecting solder 57 as one example of a second solder is disposed on the magnetic head terminal 25 that is exposed from the lower side thereof. That is, the suspension board with circuit 5 includes the slider connecting solder 57 that is disposed on the magnetic head terminal 25.

The slider connecting solder 57 is disposed on the lower surface (to be more specific, the plating layer 32) of the magnetic head terminal 25. The slider connecting solder 57 is a solder bump, and protrudes toward the lower side. The lower end portion of the slider connecting solder 57 is positioned in the lower side (the opposite side to the base insulating layer 8 relative to the cover insulating layer 10) with respect to the lower surface of the cover insulating layer 10.

Examples of a metal atom contained in the slider connecting solder 57 include Sn, Ag, Cu, Bi, Ni, and In. Preferably, the slider connecting solder 57 consists of only Sn, Ag, and Cu.

Although not shown, an external connecting solder is disposed on the external connecting terminal 27 that is exposed from the lower side thereof in the same manner as the magnetic head terminal 25.

(1-2) Frame Body and Connecting Portion

Next, the frame body 11 and the connecting portion 12 are described with reference to FIGS. 1 and 4.

The frame body 11 collectively supports the plurality of suspension boards with circuit 5. The frame body 11 has a rectangular frame shape, and the suspension group 2 is disposed in an opening 11A that is defined by the frame body 11. In this manner, the frame body 11 surrounds the suspension group 2. The frame body 11 is united with the above-described metal supporting body 7 (ref: FIG. 6A), and the frame body 11 and the metal supporting body 7 are positioned in the same plane.

The plurality of connecting portions 12 connect the plurality of suspension boards with circuit 5 to the frame body 11. The plurality of connecting portions 12 correspond to the plurality of suspension boards with circuit 5. As shown in FIG. 4, the board assembly 1 includes the plurality (two pieces) of connecting portions 12 with respect to the one suspension board with circuit 5.

Each of the plurality of connecting portions 12 corresponding to each of the suspension boards with circuit 5 includes a front-side connecting portion 37 and a rear-side connecting portion 38. The front-side connecting portion 37 connects the stage 13 to the frame body 11 that is positioned at the front side of the corresponding suspension board with circuit 5, and the rear-side connecting portion 38 connects the rear end portion of the suspension main body 14 to the frame body 11 that is positioned at the rear side of the corresponding suspension board with circuit 5.

2. Assembly Disposing Step

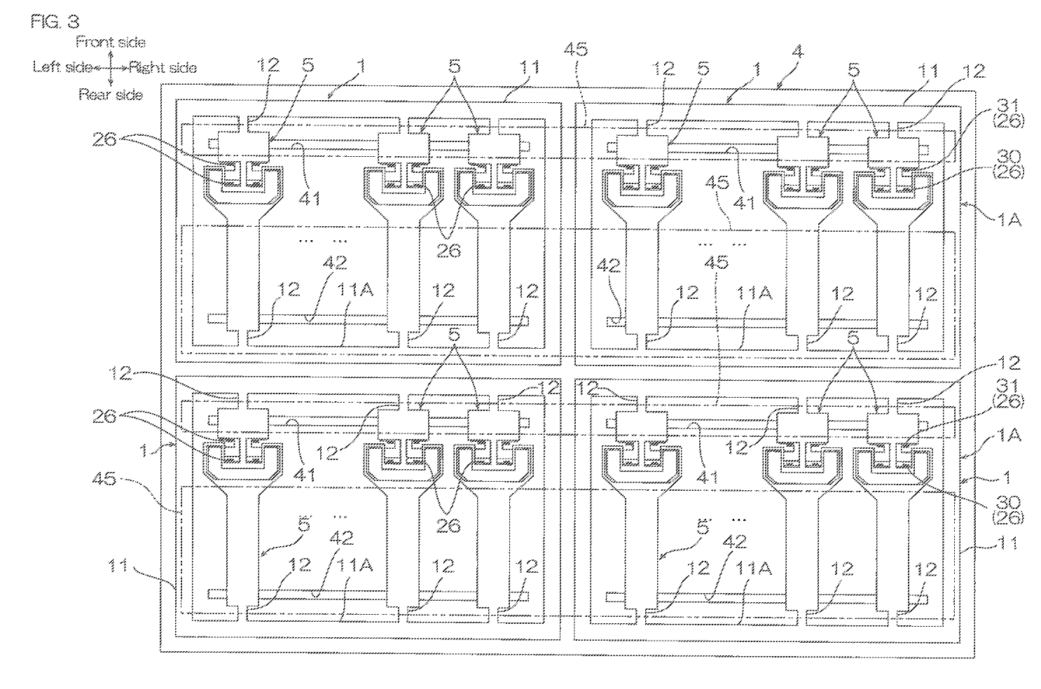

Next, in the assembly disposing step, as shown in FIG. 3, the plurality of board assemblies 1 prepared in the preparing step are disposed on the carrier board 4 to be in alignment.

(2-1) Carrier Board

First, the carrier board 4 is described with reference to FIGS. 2, 6A, and 6B.

As shown in FIG. 2, the carrier board 4 has a flat plate shape, and has an area in which the plurality of board assemblies 1 can be disposed. The carrier board 4 has heat resistance, and fails to be deformed and/or deteriorated in the reflow step to be described later. As shown in FIG. 6A, the carrier board 4 includes a base plate 50 and a pressure-sensitive adhesive layer 51 that is disposed at the upper side of the base plate 50 (one side in the thickness direction of the base plate 50).

The base plate 50 is a supporting body that supports the pressure-sensitive adhesive layer 51. The base plate 50 has rigidity. Examples of a material of the base plate 50 include fiber reinforced epoxy resin (for example, glass epoxy resin or the like), polyether sulfone, polyacrylate, polyimide, aluminum, alumina, aluminum nitride, aluminum alloy, stainless steel, and magnesium alloy. Of the material of the base plate 50, preferably, aluminum and glass epoxy resin are used, further more preferably, in view of suppressing deformation of the base plate 50, aluminum is used.

The pressure-sensitive adhesive layer 51 is laminated on the upper surface of the base plate 50. The pressure-sensitive adhesive layer 51 has tackiness for fixing the position of the plurality of board assemblies 1 to the carrier board 4. The pressure-sensitive adhesive layer 51 has heat resistance of failing to be deformed in the reflow step to be described later. Examples of a material of the pressure-sensitive adhesive layer 51 include a fluorine-based pressure-sensitive adhesive and a silicone pressure-sensitive adhesive. Preferably, a fluorine-based pressure-sensitive adhesive is used.

That is, the carrier board 4 preferably includes a fluorine-based pressure-sensitive adhesive layer 51 for fixing the position of the plurality of board assemblies 1.

When the pressure-sensitive adhesive layer 51 is the fluorine-based pressure-sensitive adhesive layer 51, the adhesive properties of the fluorine-based pressure-sensitive adhesive layer 51 with the board assembly 1 in the reflow step to be described later are preferably adjusted, and the occurrence of a wrinkle in the board assembly 1 can be suppressed.

Although not shown, the pressure-sensitive adhesive layer 51 may be attached to the base plate 50 with a known heat resistance double-sided tape.

As shown in FIG. 2, the carrier board 4 has first recessed portions 41 and second recessed portions 42 as one example of a recessed portion. The one first recessed portion 41 and the one second recessed portion 42 correspond to each of the plurality of board assemblies 1.

As shown in FIGS. 2 and 6B, the first recessed portion 41 corresponds to the plurality of slider connecting solders 57 included in the board assembly 1. The first recessed portion 41 has a recessed shape that is recessed from the upper surface of the pressure-sensitive adhesive layer 51 toward the lower side, and extends in the right-left direction.

The second recessed portion 42 corresponds to the plurality of external connecting solders (not shown) included in the board assembly 1. The second recessed portion 42 is positioned at the rear side of the first recessed portion 41 at spaced intervals thereto. The second recessed portion 42 has a recessed shape that is recessed from the upper surface of the pressure-sensitive adhesive layer 51 toward the lower side, and extends hi the right-left direction.

(2-2) Arrangement of Plurality of Board Assemblies

To dispose the plurality of board assemblies 1 on the carrier board 4 to be in alignment, the plurality of board assemblies 1 are disposed on the carrier board 4 so as to dispose the plurality of slider connecting solders 57 in the first recessed portion 41, and dispose the plurality of external connecting solders (not shown) in the second recessed portion 42.

In this manner, the cover insulating layer 10 of each of the board assemblies 1 is brought into contact with the pressure-sensitive adhesive layer 51 of the carrier board 4. The pressure-sensitive adhesive layer 51 fixes the position of each of the board assemblies 1 to the carrier board 4 with its tackiness.

As shown in FIG. 3, a plurality (two pieces) of rows 1A in which the plurality (two pieces) of board assemblies 1 are in alignment in the right-left direction are disposed on the carrier board 4 in the front-rear direction.

The plurality of element mounting terminals 26 included in the plurality of board assemblies 1 that are included in the same row 1A are positioned so as to be overlapped with each other when projected in the right-left direction. To be more specific, all of the plurality of first mounting terminals 30 included in the same row 1A are overlapped with each other when projected in the right-left direction, and all of the plurality of second mounting terminals 31 included in the same row 1A are overlapped with each other when projected in the right-left direction.

The plurality of element mounting terminals 26 included in the plurality of suspension boards with circuit 5 that are in alignment in the front-rear direction are positioned so as to be overlapped with each other when projected in the front-rear direction.

(2-3) Holding Jig

As shown in FIGS. 3 and 6B, in the assembly disposing step, preferably, a holding jig 45 is disposed at the upper side of the board assembly 1 (one side in the thickness direction of the board assembly 1).

In this manner, the plurality of board assemblies 1 are sandwiched between the carrier board 4 and the holding jig 45. Thus, the plurality of board assemblies 1 are surely in tight contact with the pressure-sensitive adhesive layer 51. As a result, in the reflow step, heat can be efficiently transmitted to the plurality of board assemblies 1, and the plurality of element connecting solders 56 (described later) can be surely melted.

The holding jig 45 has a generally flat plate shape. An example of a material of the holding jig 45 includes a metal material such as aluminum and stainless steel.

The arrangement of the holding jig 45 is not particularly limited as long as the plurality of element mounting terminals 26 can be exposed from the upper side. As shown in FIG. 3, for example, the plurality of holding jigs 45 extending is the right-left direction are prepared, and collectively disposed at the upper side of the plurality of board assemblies 1 included in the same row 1A. The plurality of holding jigs 45 are positioned at spaced intervals in the front-rear direction so as to expose the plurality of element mounting terminals 26 from the upper side thereof.

3. Solder Disposing Step, Element Disposing Step, and Reflow Step

(3-1) Solder Disposing Step

Next, in the solder disposing step, as shown in FIG. 7A, the element connecting solder 56 is disposed on each of the element mounting terminals 26 of the plurality of suspension boards with circuit 5.

To be more specific, the element connecting solders 56 are simultaneously disposed on the upper surface of the plating layer 32 of the plurality of element mounting terminals 26 (the first mounting terminal 30 and the second mounting terminal 31) by a known method (for example, printing with a known printer, application with a dispenser, or the like). In the embodiment, a moving direction (printing direction) of the printer and the dispenser is the right-left direction, and the element connecting solders 56 are collectively disposed in the plurality of element mounting terminals 26 that are in alignment in the right-left direction (ref: FIG. 3).

As the composition of the element connecting solder 56, for example, the composition that is the same as feat of the above-described slider connecting solder 57 is used. Preferably, the element connecting solder 56 consists of only Sn, Ag, and Cu.

(3-2) Element Disposing Step

Next, in the element disposing step, as shown in FIG. 7B, the piezoelectric element 58 as one example of an electronic element is disposed so as to be in contact with the element connecting solders 56 disposed on each of the plurality of element mounting terminals 26.

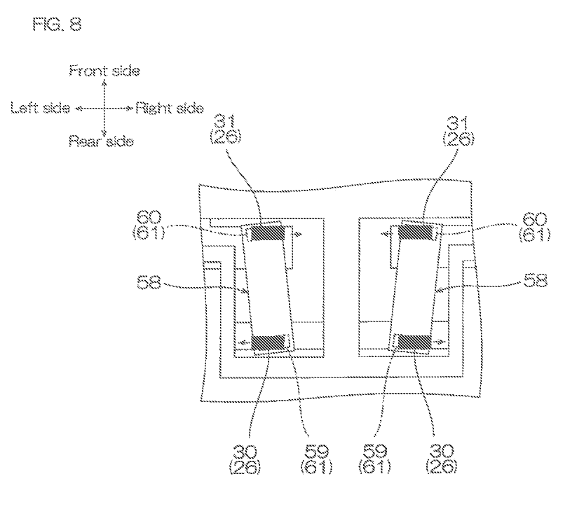

The piezoelectric element 58 is an actuator that is capable of expanding and contracting in the front-rear direction. By supplying tire electricity thereto and controlling the voltage thereof it expands and contracts. In the embodiment, the two piezoelectric elements 58 are mounted on each of the suspension, hoards with circuit 5 (ref: FIG. 8).

The piezoelectric element 58 is, for example, formed of a known piezoelectric material, to be more specific, piezoelectric ceramics or the like.

The piezoelectric element 58 includes a plurality of element terminals 61. The plurality of element terminals 61 correspond to the plurality of element mounting terminals 26, and include a first element terminal 59 and a second element terminal 60. The first element terminal 59 and the second element terminal 60 are disposed at spaced intervals to each other in the front-rear direction.

In the element disposing step, the piezoelectric element 58 is disposed so that the first element terminal 59 is in contact with the element connecting solder 56 on the first mounting terminal 30, and the second element terminal 60 is in contact with the element connecting solder 56 on the second mounting terminal 31.

(3-3) Reflow Step

Next, in the reflow step, as shown in FIG. 7C, the element connecting solders 56 are heated so as to he dissolved, and the piezoelectric element 58 is connected to the plurality of element mounting terminals 26.

The heating temperature (the reflow temperature) is appropriately changed according to the composition of the solder, and is, for example, 120° C. or more, preferably 130° C. or more, and for example, 280° C. or less, preferably 260° C. or less. When the element connecting solder 56 consists of only Sn, Ag, and Cu, the heating temperature (the reflow temperature) is, for example, 230° C. or more, preferably 240° C. or more, and for example, 280° C. or less, preferably 260° C. or less.

The heating time (the reflow time) is, for example, 3 seconds or more, preferably 5 seconds or more, and for example, 300 seconds or less, preferably 200 seconds or less.

Is the reflow step, as shown in FIG. 8, the piezoelectric element 58 is connected to the plurality of element mounting terminals 26, while being self-aligned. To be more specific, in the step of disposing the piezoelectric element 58 (ref: FIG. 7B), there may the a case where the piezoelectric element 58 deviates from a predetermined position, and is disposed so as to tilt in the right-left direction. In this case, when viewed in the up-down direction, the center of the first element terminal 59 deviates from the center of the first mounting terminal 30, and the center of the second element terminal 60 deviates from the center of the second mounting terminal 31.

When the element connecting solder 56 is reflowed so as to be dissolved, the element connecting solder 56 is melted on the entire upper surface (to be more specific, the plating layer 32) of each of the first mounting terminal 30 and the second mounting terminal 31 so as to wetly spread (ref: FIG. 7C).

At this time, by the surface tension of the melted element connecting solder 56, power is applied to the piezoelectric element 58 so that the center of the first element terminal 59 coincides with the center of the first mounting terminal 30, and the center of the second element terminal 60 coincides with the center of the second mounting terminal 31 when viewed in the up-down direction. In this manner, the piezoelectric element 58 is self-aligned from a state of deviating from the predetermined position toward the predetermined position.

As shown in FIG. 7C, the element connecting solder 56 connects the first mounting terminal 30 to the first element terminal 59, and connects the second mounting terminal 31 to the second element terminal 60.

In this manner, the element connecting solder 56 is disposed between each of the element terminals 61 and each of the element mounting terminals 26 (between the first element terminal 59 and the first mounting terminal 30, and between the second element terminal 60 and the second mounting terminal 31).

Each of the element connecting solders 56 has a thickness of for example, 3 μm or more, preferably 10 μm or more, further more preferably 15 μm or more, and for example, 50 μm or less, preferably 40 μm or less, further more preferably 30 μm or less, particularly preferably 25 μm or less,

When the thickness of each of the element connecting solders 56 is the above-described lower limit or more, the piezoelectric element 58 can be stably self-aligned, and improvement of the position accuracy of the piezoelectric element 58 in the front-rear and right-left directions (XY direction) can be surely achieved. When the thickness of each of the element connecting solders 56 is the above-described upper limit or less, in the case where a suspension board with circuit assembly 150 (described later) is mounted on a hard disk drive (not shown), the contact of the piezoelectric element 58 with members around it can be suppressed.

(3-4) Continuous Performance

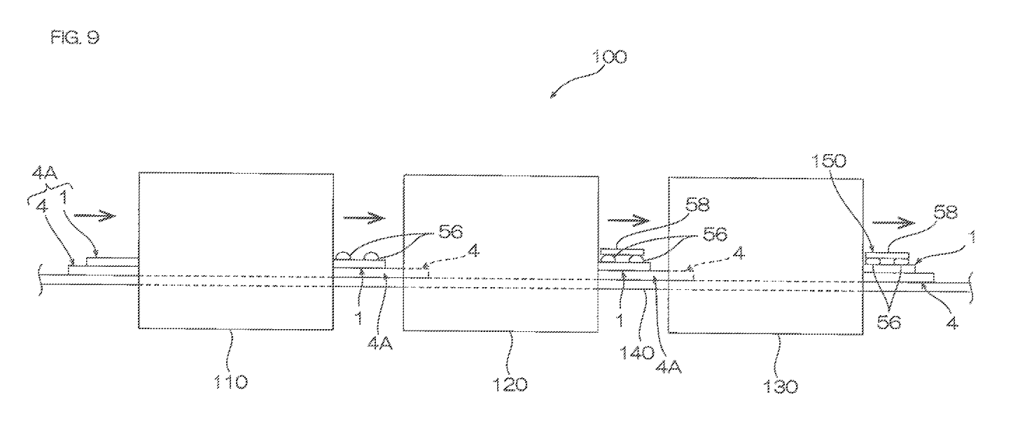

The solder disposing step, the element disposing step, and the reflow step described above are continuously performed. To be more specific, the solder disposing step, the element disposing step, and the reflow step are continuously performed by a continuous mounting line 100 shown in FIG. 9.

The continuous mounting line 100 includes a solder printing device 110, an element mounting device 120, a reflow oven 130, and a conveyor 140.

The solder printing device 110 is capable of performing the above-described solder disposing step. Examples of the solder printing device 110 include a known solder printer and a dispenser. The element mounting device 120 is capable of performing the above-described element disposing step. As example of the element mounting device 120 includes a known electronic component mounting device. The reflow oven 130 is capable of performing the above-described reflow step. An example of the reflow oven 130 includes a known heating oven.

The conveyor 140 conveys the carrier board 4 in which the plurality of board assemblies 1 are disposed so as to sequentially pass the solder printing device 110, the element mounting device 120, and the reflow oven 130. That is, the conveyor 140 conveys the carrier board 4 in which the plurality of board assemblies 1 are disposed so as to sequentially perform the solder disposing step, the element disposing step, and the reflow step. The conveyor 140 passes the solder printing device 110, the element mounting device 120, and the reflow oven 130.

In the continuous mounting line 100, first, the carrier board 4 in which the plurality of board assemblies 1 are disposed by the above-described assembly disposing step (hereinafter, defined as an assembly disposing board 4A) is disposed on the conveyor 140. Then, the conveyor 140 conveys the assembly disposing board 4A to the solder printing device 110.

In the solder printing device 110, when the assembly disposing board 4A passes the solder printing device 110, the above-described solder disposing step is performed, and the element connecting solder 56 is disposed on the plurality of element mounting terminals 26.

Next, the conveyor 140 conveys the assembly disposing board 4A in which the element connecting solder 56 is disposed from the solder printing device 110 to the element mounting device 120 (from the solder disposing step to the element disposing step).

In the element mounting device 120, when the assembly disposing board 4A passes the element mounting device 120, the above-described element disposing step is performed, and the piezoelectric element 58 is disposed so as to be in contact with the plurality of element connecting solders 56.

Next, the conveyor 140 conveys the assembly disposing board 4A in which the piezoelectric element 58 is disposed fern the element mounting device 120 to the reflow oven 130 (from the element disposing step to the reflow step).

In the reflow oven 130, when the assembly disposing board 4A passes the reflow oven 130, the above-described reflow step is performed, and the element connecting solder 56 is heated to be dissolved, and the piezoelectric element 58 is connected to the plurality of element mounting terminals 26.

As described above, the suspension board with circuit assembly 150 mounted with the piezoelectric element 58 is produced. As shown in FIG. 7C, the suspension board with circuit assembly 150 includes the board assembly 1, the piezoelectric element 58, and the element connecting solders 56 that are disposed between each of the element terminals 61 and each of the element mounting terminals 26.

Thereafter, the connecting portions 12 are cut, and the plurality of suspension boards with circuit 5 are separated from the frame body 11 as needed.

In the first embodiment as shown in FIG. 3, the plurality of board assemblies 1 are disposed on the carrier board 4 to be in alignment. Thus, as shown in FIG. 9, the plurality of board assemblies 1 can be collectively conveyed, and the solder disposing step, the element disposing step, and the reflow step can be continuously performed with respect to the plurality of board assemblies 1.

As a result, unevenness in the amount of the element connecting solder 56 disposed on the element mounting terminal 26 and unevenness in the reflow temperature with respect to the element connecting solder 56 among the plurality of board assemblies 1 can be suppressed. In this manner, unevenness in the position of the piezoelectric element 58 with respect to each of the suspension boards with circuit 5 among the plurality of board assemblies 1 can be suppressed.

In this manner, improvement of the position accuracy of the piezoelectric element 58 can be achieved, and improvement of the production efficiency of the suspension board with circuit assembly 150 can be achieved.

As shown in FIG. 7C, the suspension main body 14 (ref: FIG. 2) is supported by a load beam 66, so that the suspension board with circuit assembly 150 is mounted on a hard disk drive (not shown). At this time, the front end portion of the load beam 66 is positioned at the upper side (the other side in the thickness direction) with respect to the piezoelectric element 58.

Thus, when the position accuracy of the piezoelectric element 58 is low, and the thickness of each of the element connecting solders 56 is above the above-described range, the piezoelectric element 58 is in contact with the load beam 66. Meanwhile, in the above-described embodiment, improvement of the position accuracy of the piezoelectric element 58 can be achieved, and the thickness of each of the element connecting solders 56 can be the above-described upper limit or less, so that the contact of the piezoelectric element 58 with the load beam 66 can be suppressed.

As shown in FIG. 6B, the plurality of board assemblies 1 are disposed on the carrier board 4 so that the slider connecting solder 57 is disposed in the first recessed portion 41. Thus, the contact of the slider connecting solder 57 with the carrier board 4 can be suppressed. As a result, the position deviation of the element mounting terminal 26 can be suppressed, and in the solder disposing step, the element connecting solder 56 can be accurately disposed on the element mounting terminal 26.

As shown in FIG. 6A, the carrier board 4 includes the fluorine-based pressure-sensitive adhesive layer 51. The position of the plurality of board assemblies 1 is fixed by the fluorine-based pressure-sensitive adhesive layer 51. Thus, compared to a silicone-based pressure-sensitive adhesive layer, the adhesive properties of the fluorine-based pressure-sensitive adhesive layer 51 with the board assembly 1 in the reflow step are preferably adjusted, and the occurrence of a wrinkle in the board assembly 1 can be suppressed.

As shown in FIG. 8, in the reflow step, the piezoelectric element 58 is connected to the element mounting terminal 26, while being sell-aligned. Thus, improvement of the position accuracy of the piezoelectric element 58 can be achieved.

### SECOND EMBODIMENT

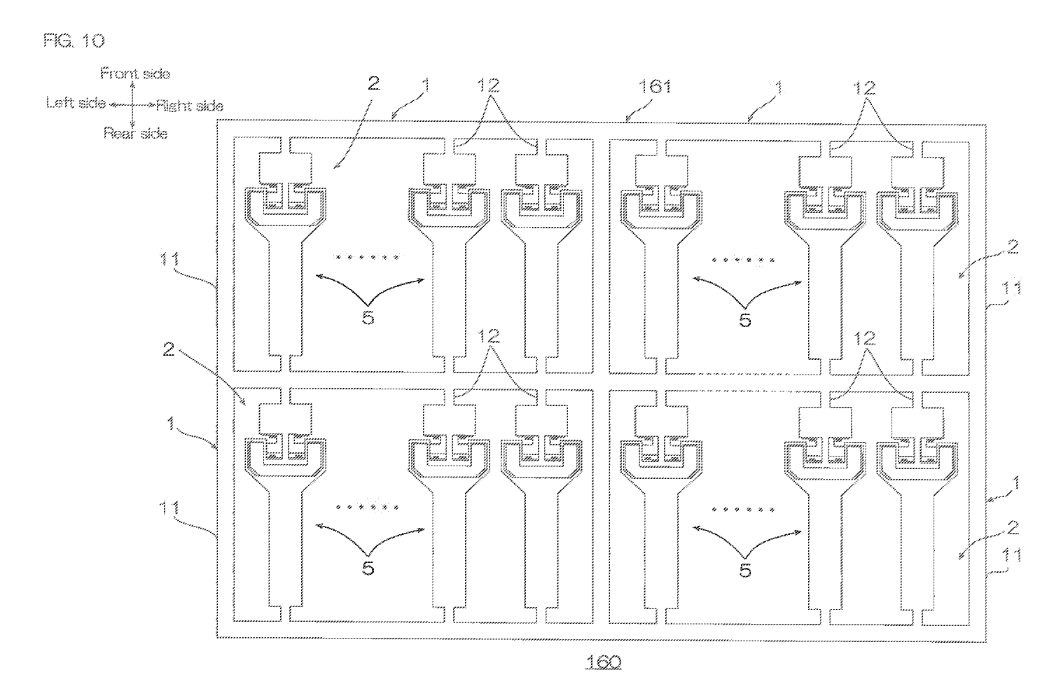

Next, a second embodiment of the present invention is described with reference to FIG. 10. In the second embodiment, the same reference numerals are provided for members and steps corresponding to those described in the above-described first embodiment, and their detailed description is omitted.

In the first embodiment, as shown in FIG. 1 the plurality of board assemblies 1 are separated. However, in the present invention, the pattern is not limited to this. In the second embodiment, as shown in FIG. 10, the plurality of board assemblies 1 may be united.

In the second embodiment, first, an assembly sheet 160 integrally including the plurality of board assemblies 1 is prepared (the preparing step). In this manner, the plurality of board assemblies 1 can be also prepared.

In the assembly sheet 160, the frame bodies 11 included in the plurality of board assemblies 1 are connected to each other. To be more specific, the assembly sheet 160 includes the plurality of suspension groups 2, a lattice frame 161 as one example of a supporting portion, and a plurality of connecting portions 12. The lattice frame 161 is made up of the plurality of frame bodies 11, and has a lattice shape. The lattice frame 161 defines the plurality of suspension groups 2. The plurality of connecting portions 12 connect the plurality of suspension boards with circuit 5 to the lattice frame 161.

Then, the assembly sheet 160 is disposed on the carrier board 4 (the assembly disposing step). In this manner, the plurality of board assemblies 1 are disposed on the carrier board 4 to be in alignment.

Thereafter, the solder disposing step, the element disposing step, and the reflow step are continuously perforated in the same manner as the first embodiment. In this manner, the suspension board with circuit assembly 150 can be also produced, and the same function and effect as that of the first embodiment can be achieved.

### MODIFIED EXAMPLE

In the first embodiment and the second embodiment described above, the carrier board 4 has the first recessed portion 41 and the second recessed portion 42 as one example of a recessed portion. However, the pattern is not limited to this. As shown in FIG. 6B, the carrier board 4 can also have an opening 43 (ref: phantom line of FIG. 6B) instead of the recessed portion. The opening 43 passes through the carrier board 4 in the up-down direction.

In the first embodiment and the second embodiment described above, the slider connecting solder 57 is disposed on the magnetic head terminal 25. However, the pattern is not limited to this. The slider connecting solder 57 may also not be provided. In this case, the carrier board 4 may not have a recessed portion and/or an opening.

In the first embodiment and the second embodiment described above, the printing direction (the moving direction of the printer and the dispenser) in the solder disposing step is the right-left direction. However, the direction is not limited to this. The printing direction in the solder disposing step may be also the front-rear direction.

In the above-described embodiments, the same function and effect as that of the first embodiment can be achieved.

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

What is claimed is:

1. A method for producing a suspension board with circuit assembly comprising:
a preparing step of preparing a plurality of board assemblies each of which includes a plurality of suspension boards with circuit including a first terminal and disposed at spaced intervals to each other, a supporting portion collectively supporting the plurality of suspension boards with circuit, and a plurality of connecting portions connecting each of the plurality of suspension boards with circuit to the supporting portion;
an assembly disposing step of disposing the plurality of board assemblies on a carrier board to be in alignment;
a solder disposing step of disposing a first solder on the first terminal of each of the plurality of suspension boards with circuit;
an element disposing step of disposing an electronic element so as to be in contact with the first solder disposed on each of the plurality of first terminals; and
a reflow step of heating the first solder to be dissolved and connecting the electronic element to the first terminal, wherein
the solder disposing step, the element disposing step, and the reflow step are continuously performed.

2. The method for producing a suspension board with circuit assembly according to claim 1, wherein
the first terminal is exposed when viewed from one side in a thickness direction of the suspension board with circuit,
each of the plurality of suspension boards with circuit further includes a second terminal exposed when viewed from the other side in the thickness direction of the suspension board with circuit and a second solder disposed on the second terminal,
the carrier board has a recessed portion and/or an opening, and
in the assembly disposing step, the plurality of board assemblies are disposed on the carrier board so that the second solder is disposed in the recessed portion and/or the opening.

3. The method for producing a suspension board with circuit assembly according to claim 1, wherein
the carrier board includes a fluorine-based pressure-sensitive adhesive layer for fixing the position of the plurality of board assemblies.

4. The method for producing a suspension board with circuit assembly according to claim 1, wherein
the electronic element is a piezoelectric element, and
in the reflow step, the piezoelectric element is connected to the first terminal, while being self-aligned.
